(19) United States
(12) Patent Application Publication
(10) Pub. No.: US 2021/0316416 A1
(43) Pub. Date: Oct. 14, 2021

(54) FOCUS RING AND SUBSTRATE PROCESSING APPARATUS

(71) Applicant: Tokyo Electron Limited, Tokyo (JP)

(72) Inventors: Taketoshi TOMIOKA, Miyagi (JP); Yasuharu SASAKI, Miyagi (JP); Hiroki KISHI, Miyagi (JP); Jisoo SUH, Miyagi (JP)

(21) Appl. No.: 17/358,100

(22) Filed: Jun. 25, 2021

Related U.S. Application Data
(62) Division of application No. 15/248,118, filed on Aug. 26, 2016.

(30) Foreign Application Priority Data
Sep. 4, 2015 (JP) 2015-175045

(51) Int. Cl. B24B 37/32; B24B 37/20

(52) U.S. Cl. CPC B24B 37/32; B24B 37/20

(57) ABSTRACT

A focus ring is disposed on a peripheral portion of a lower electrode that receives a substrate thereon in a process container so as to contact a member of the lower electrode. The focus ring includes a contact surface that contacts the member of the lower electrode and is made of any one of a silicon-containing material, alumina and quartz. At least one of the contact surface of the focus ring and a contact surface of the member of the lower electrode has surface roughness of 0.1 micrometers or more.

### CROSS-REFERENCE TO RELATED APPLICATIONS

This patent application is a divisional application of and claims the benefit of priority under 35 U.S.C. 120 of patent application Ser. No. 15/248,118 filed on Aug. 26, 2016, which claims priority to Japanese Patent Application No. 2015-175045, filed on Sep. 4, 2015, the entire contents of which are incorporated herein by reference.

### BACKGROUND OF THE INVENTION

### 1. Field of the Invention

The present invention relates to a focus ring and a substrate processing apparatus.

### 2. Description of the Related Art

A focus ring is disposed at a peripheral portion of a lower electrode that receives a substrate in a process chamber. The back surface of the focus ring often has a mirror-like surface. In contrast, International Publication No. WO 2010/109848, Japanese Laid-Open Patent Application Publication No. 2011-151280 and Japanese Laid-Open Patent Application Publication No. 11-61451 propose that concavities and convexities are provided in a surface by processing the back surface or the top surface so as to have a predetermined roughness level.

In International Publication No. WO 2010/109848, a polyimide tape is provided on the concavities and convexities formed in the back surface of the focus ring, and the focus ring and a dielectric plate supporting the focus ring are glued together by deforming the tape.

In Japanese Laid-Open Patent Application Publication No. 2011-151280, by providing the concavities and convexities in the back surface of the focus ring, heat release characteristics are improved, and an increase in contact thermal resistance is prevented.

In Japanese Laid-Open Patent Application Publication No. 11-61451, by providing the concavities and convexities in the top surface of the focus ring, a period of time for an auxiliary discharge that is performed to prevent foreign substances from being generated immediately after mounting the focus ring on the lower electrode. Thus, a problem of decreasing productivity due to the extended period for the auxiliary discharge is solved.

However, International Publication No. WO 2010/109848, Japanese Laid-Open Patent Application Publication No. 2011-151280 and Japanese Laid-Open Patent Application Publication No. 11-61451 do not describe measures to solve a problem of decreasing a force of an electrostatic chuck for attracting the focus ring thereon when the focus ring has the mirror-like back surface.

In the meantime, when process time is extended, the force for attracting the focus ring gradually weakens, and as a result, an amount of leak of a heat transfer gas supplied to a gap between the electrostatic chuck and the focus ring increases.

### SUMMARY OF THE INVENTION

Accordingly, to solve the above discussed problems, embodiments of the present invention are intended to stabilize attraction characteristics of a focus ring.

According to one embodiment of the present invention, there is provided a focus ring disposed on a peripheral portion of a lower electrode that receives a substrate thereon in a process container so as to contact a member of the lower electrode. The focus ring includes a contact surface that contacts the member of the lower electrode and is made of any one of a silicon-containing material, alumina and quartz. At least one of the contact surface of the focus ring and a contact surface of the member of the lower electrode has surface roughness of 0.1 micrometers or more.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are simply illustrative examples and are not restrictive of the invention as claimed.

### BRIEF DESCRIPTION OF THE DRAWINGS

FIG. 1 illustrates an example of a vertical cross section of a substrate processing apparatus according to an embodiment;

FIGS. 2A through 2C illustrate examples of states of electric charge between a mirror-like focus ring and an electrostatic chuck according to an embodiment;

FIGS. 3A through 3C illustrate examples of states of electric charge between a focus ring and an electrostatic chuck according to an embodiment;

FIGS. 4A and 4B show relationships between roughness of a back surface of a focus ring and a leakage quantity of a heat transfer gas of a working example according to an embodiment and a comparative example;

FIG. 5 shows a relationship between roughness of a back surface of a focus ring and a leakage quantity of a heat transfer gas of a working example according to an embodiment and a comparative example; and

FIGS. 6A and 6B show relationships between roughness of a back surface of a focus ring and a leakage quantity of a heat transfer gas of a working example according to an embodiment and a comparative example.

### DETAILED DESCRIPTION OF THE PREFERRED EMBODIMENTS

Embodiments of the present invention are described below, with reference to accompanying drawings. Note that elements having substantially the same functions or features may be given the same reference numerals and overlapping descriptions thereof may be omitted.

[Overall Configuration of Substrate Processing Apparatus]

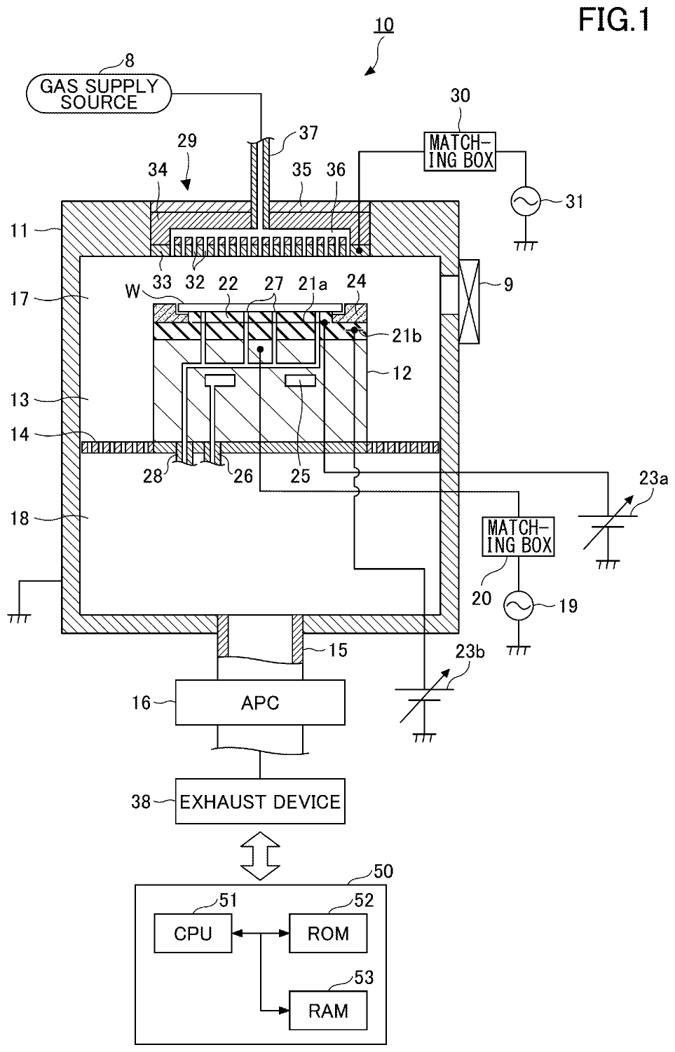

To begin with, the overall configuration of a substrate processing apparatus 10 according to an embodiment of the present invention is described below, with reference to FIG. 1. The substrate processing apparatus 10 is made of aluminum and the like, and includes a cylindrical process container 11 the inside of which can be sealed. The process container 11 is connected to the ground potential. The process container 11 includes a pedestal 12 therein that is made of a conductive material such as aluminum. The pedestal 12 is a columnar stand to receive a semiconductor wafer W (which is hereinafter referred to as a “wafer W”) thereon, and also serves as a lower electrode.

An exhaust passage 13 that is a passage to pump a gas above the pedestal 12 out of the process container 11 is formed between a side wall of the process container 11 and a side wall of the pedestal 12. An exhaust plate 14 is disposed in the middle of the exhaust passage 13. The exhaust plate 14 is a plate-shaped member having many holes, and serves as a partition plate that separates the process container 11 into an upper part and a lower part. The upper part separated by the exhaust plate 14 is a process chamber 17 in which a plasma process is performed. The lower part of the process container 11 separated by the exhaust plate 14 is an exhaust chamber (manifold) 18. An exhaust device 38 is connected to the exhaust chamber 18 through an exhaust pipe 15 and an APC (Adaptive Pressure Control: Automatic Pressure Control) valve 16. The exhaust plate 14 acquires plasma generated in the process chamber 17, and prevents the plasma from leaking into the exhaust chamber 18. The exhaust device 38 pumps a gas in the process container 11 and reduces the pressure inside the process chamber 17 to a predetermined pressure by being adjusted by the APC valve 16. Thus, the inside of the process chamber 17 is maintained at a predetermined degree of vacuum.

A first radio frequency power source 19 is connected to the pedestal 12 through a matching box 20, and supplies radio frequency power RF of a relatively low frequency (which is also referred to as “radio frequency power LF” (Low Frequency)), for example, appropriate for attracting ions in plasma to the wafer W on the pedestal 12 such as 13.56 MHz. The matching box 20 prevents reflection of the radio frequency power from the pedestal 12, and maximizes power supply efficiency of the radio frequency power LF for bias.

An electrostatic chuck 22 containing an electrostatic electrode plate 21a and an electrostatic electrode plate 21b therein is disposed on the pedestal 12. The electrostatic chuck 22 may be made of an insulator or a metal such as aluminum on which ceramics and the like are sprayed. A direct-current power source 23a is connected to the electrostatic electrode plate 21a, and a direct-current power source 23b is connected to the electrostatic electrode plate 21b. When a wafer W is placed on the pedestal 12, the wafer W is placed on the electrostatic chuck 22. The electrostatic chuck 22 is provided on the pedestal 12, and is an example of an electrostatic attraction mechanism that electrostatically attracts the wafer W thereon. The electrostatic attraction mechanism includes an electrostatic attraction mechanism for substrate and an electrostatic attraction mechanism for focus ring. The electrostatic electrode plate 21a and the direct-current power source 23a are an example of the electrostatic attraction mechanism for substrate, and the electrostatic electrode plate 21b and the direct-current power source 23b are an example of the electrostatic attraction mechanism for focus ring.

An annular focus ring 24 is placed on the peripheral portion of the electrostatic chuck 22 so as to surround the outer edge of the wafer W. The focus ring 24 is made of a conductive member, for example, silicon, and converges the plasma in the process chamber 17 toward the surface of the wafer W, thereby improving the efficiency of an etching process.

The focus ring 24 is made of any of a silicon-containing material, alumina (Al₂O₃) or quartz. When the focus ring 24 is made of the silicon-containing material, the silicon-containing material includes a silicon single crystal or silicon carbide (SiC). The focus ring 24 is integrally made of any one of these materials.

When a positive direct-current voltage (which is also hereinafter referred to as “HV” (High Voltage)) is applied to the electrostatic electrode plate 21a and the electrostatic electrode plate 21b, negative potential is generated at the back surface of the wafer W and the back surface of the focus ring 24, which generates a voltage difference between the top surfaces of the electrostatic electrode plate 21a and the electrostatic electrode plate 21b and the back surfaces of the wafer M and the focus ring 24. The wafer W is electrostatically attracted to and held by the electrostatic chuck 22 due to Coulomb's force or the force of Johnson-Rahbek effect. Also, the focus ring 24 is electrostatically attracted to the electrostatic chuck 22.

Moreover, an annular refrigerant chamber 25, for example, extending in a circumferential direction, is provided within the pedestal 12. A low temperature refrigerant, for example, cooling water or Galden (Trademark) is supplied and circulated to the refrigerant chamber 25 from a chiller unit through a pipe for refrigerant 26. The pedestal 12 cooled by the low temperature refrigerant cools the wafer W and the focus ring 24 through the electrostatic chuck 22.

A surface that attracts the wafer W of the electrostatic chuck 22 (attraction surface) has a plurality of heat transfer gas supply holes 27. A heat transfer gas such as helium (He) gas is supplied to the plurality of heat transfer gas supply holes 27 through a heat transfer gas supply line 28. The heat transfer gas is supplied to a gap between the top surface of the electrostatic chuck 22 and the back surface of the wafer W and a gap between the top surface of the electrostatic chuck 22 and the back surface of the focus ring 24 through the plurality of heat transfer gas supply holes 27, and serves to transfer heat of the wafer M and the focus ring 24 to the electrostatic chuck 22.

A gas shower head 29 is disposed in a ceiling part of the process container 11 so as to face the pedestal 12. A second radio frequency power source 31 is connected to the gas shower head 29 through a matching box 30, and supplies radio frequency power RF of a relatively high frequency (which is also referred to as “radio frequency power HF” (High Frequency)), for example, appropriate for generating plasma in the process container 11 such as 60 MHz, to the shower head 29.

Thus, the gas shower head 29 also functions as an upper electrode. The matching box 30 prevents the reflection of the radio frequency power from the gas shower head 29, and maximizes the power supply efficiency of the radio frequency power HF for plasma excitation. The radio frequency power HF supplied from the second radio frequency power source 31 may be also supplied to the pedestal 12.

The gas shower head 29 includes a ceiling electrode plate 33 having many gas holes 32, a cooling plate 34 supporting the ceiling electrode plate 33 from above, and a lid body 35 covering the cooling plate 34. A buffer chamber 36 is provided inside the cooling plate 34, and a gas introduction pipe 37 is connected to the buffer chamber 36. The gas shower head 29 supplies a gas supplied from a gas supply source 8 through the gas introduction pipe 37 and the buffer chamber 36 to the process chamber 17 through many of the gas holes 32.

The gas shower head 29 is detachable from and attachable to the process container 11, and serves as a lid of the process container 11. By removing the gas shower head 29 from the process container 11, an operator can directly touch a wall surface of the process container 11 and component parts in the process container 11. Thus, the operator can clean the wall surface of the process container 11 and the surfaces of the component parts, and can remove extraneous matter attached to the wall surface and the like of the process container 11.

In the substrate processing apparatus 10, plasma is generated from the gas supplied from the gas shower head 29, and a plasma process such as an etching is performed on the wafer W by the plasma. Operation of each of the component parts of the substrate processing apparatus 10 is controlled by a control unit 50 that controls the entire operation of the substrate processing apparatus 10.

The control unit 50 includes a CPU (Central Processing Unit) 51, a ROM (Read Only Memory) 52, and a RAM (Random Access Memory) 53. The control unit 50 controls the plasma process such as the etching process in accordance with a procedure set in a recipe stored in the RAM 53 and the like. The function of the control unit 50 may be implemented by using software or by using hardware.

In performing a process such as the etching by using the substrate processing apparatus 10 having such a configuration, at first, a wafer W is carried into the process container 11 from an opened gate valve 9 while the wafer W is being held on a transfer arm. The gate valve 9 is closed after the wafer W is carried into the process container 11. The wafer W is held by pusher pins above the electrostatic chuck 22, and is placed on the electrostatic chuck 22 by lowering the pusher pins. Direct-current voltages HV from the direct-current power source 23a and the direct-current power source 23b are applied to the electrostatic electrode plate 21a and the electrostatic electrode plate 21b of the electrostatic chuck 22. Thus, the wafer W and the focus ring 24 are attracted to the top surface of the electrostatic chuck 22.

The pressure inside the process container 11 is reduced to a setting pressure value by the exhaust device 38 and the APC valve 16. A gas is introduced into the process container 11 from the gas shower head 29 in a form of shower, and predetermined radio frequency power is supplied into the process container 11. The introduced gas is ionized and gets dissociated by the radio frequency power, thereby generating plasma. An etching process, a film deposition process or the like is performed on the wafer W by the plasma. After that, the wafer W is held on the transfer arm, and is carried out of the process container 11.

[Back Surface of Focus Ring]

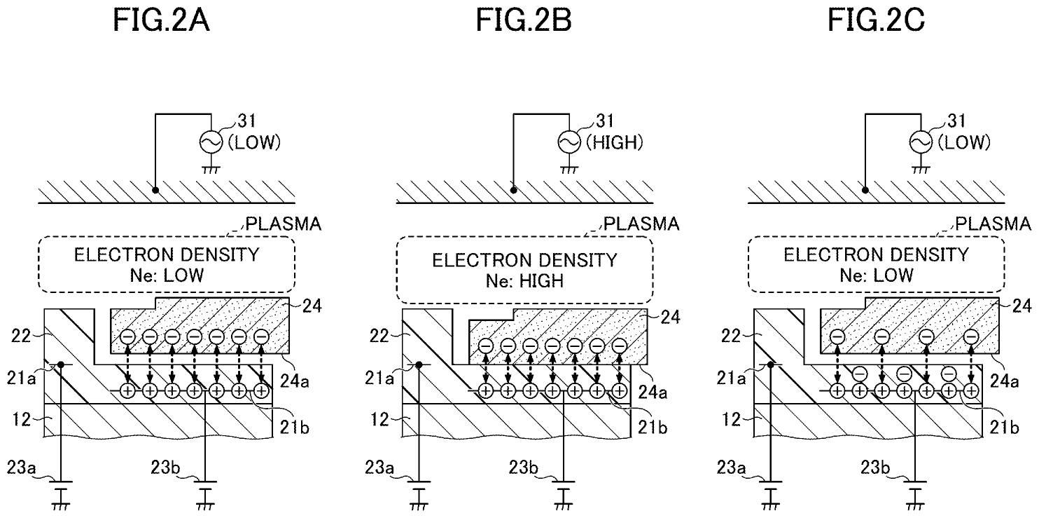

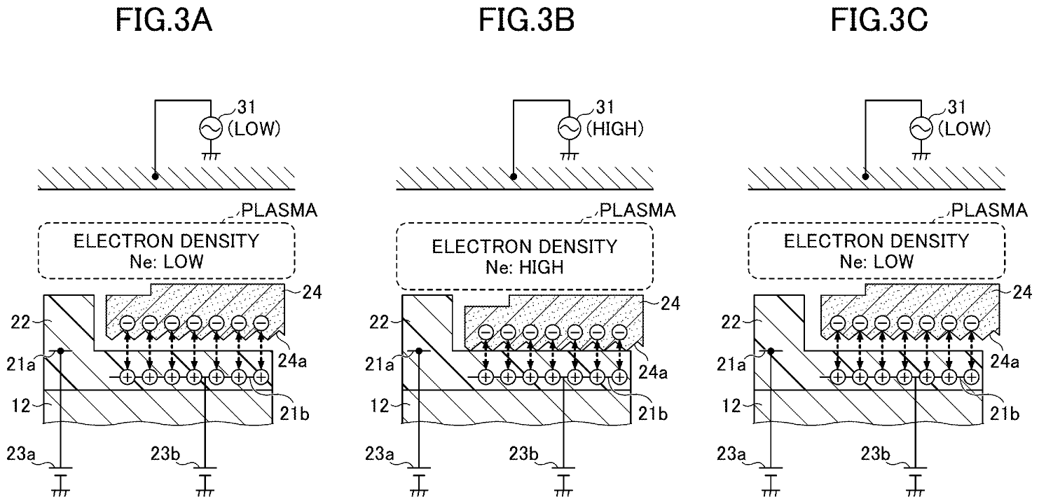

Next, surface roughness Ra and a charge transfer in the back surface of the focus ring 24 according to the present embodiment are described below with reference to FIGS. 2A through 20 and 3A through 3C. FIGS. 2A through 20 illustrate examples of states of charge between a focus ring 24 having a mirror-like (smooth) back surface and the electrostatic chuck 22. FIGS. 3A through 3C illustrate examples of states of charge between the focus ring 24 having a rough back surface according to the present embodiment and the electrostatic chuck 22.

In FIGS. 2A through 20 and 3A through 30, positive direct-current voltages HV are applied to the electrostatic electrode plate 21a and the electrostatic electrode plate 21b of the electrostatic chuck 22 from the direct-current power source 23a and the direct-current power source 23b. During each process illustrated in FIGS. 2A through 2C and 3QA through 3C, the value of the applied direct-current voltages HV is constant and does not change. In contrast, in FIGS. 2A and 3A, the plasma is generated by supplying relatively low-power radio frequency power HF for plasma generation into the process container 11 from the second radio frequency power 31.

This causes negative charge to be generated in the back surface of the focus ring 24. Thus, the positive charge in the top surface of the electrostatic chuck 22 and the negative charge in the back surface of the focus ring 24 are drawn from each other, thereby electrostatically attracting the focus ring 24 to the electrostatic chuck 22.

Next, in FIGS. 2B and 3B, plasma is generated by supplying radio frequency poser HF higher than the radio frequency power HF supplied in FIGS. 2A and 3A. As a result, the attracting force between the positive charge in the top surface of the electrostatic chuck 22 and the negative charge in the back surface of the focus ring 24 becomes stronger, and a distance between the focus ring 24 and the electrostatic chuck 22 becomes narrower.

Subsequently, in FIGS. 2C and 3C, radio frequency power HF lower than the radio frequency power supplied in FIGS. 2B and 3B is supplied to the process container 11.

In FIGS. 2A through 2C, the back surface of the focus ring 24 has a mirror-like surface, and for example, the surface roughness of the back surface of the focus ring 24 is smaller than or equal to 0.08 micrometers. In this case, when the radio frequency power HF that is higher than the radio frequency power HF supplied in FIG. 2A is suppled, as illustrated in FIG. 2B, the distance between the focus ring 24 and the electrostatic chuck 22 becomes narrower than the distance in FIG. 2A. After that, when the radio frequency power HF that is lower than the radio frequency power supplied in FIG. 2B is supplied, as illustrated in FIG. 2C, the distance between the focus ring 24 and the electrostatic chuck 22 becomes wider than the distance in FIG. 2B. On this occasion, a part of the negative charge of the focus ring 24 remains in the top surface of the electrostatic chuck 22. Thus, by supplying the radio frequency power of the low power and the high power, the negative charge transferring from the focus ring 24 to the electrostatic chuck 22 increases. As a result, an amount of negative charge in the back surface of the focus ring 24 decreases, and the attraction force of the focus ring 24 to the electrostatic chuck 22 decreases.

Depending on a process, the supply of low-power radio frequency power and high-power radio frequency power from the second radio frequency power source 31 is repeated. This repetition causes the electric charge for attracting the focus ring 24 to the electrostatic chuck 22 to be further reduced. As a result, the attracting force for attracting the focus ring 24 to the electrostatic chuck 22 further decreases, and an amount of heat transfer gas leaking from the gap between the focus ring 24 and the electrostatic chuck 22 (which is also hereinafter referred to as a “leakage quantity”) among the heat transfer gas having been supplied to the gap between the focus ring 24 and the electrostatic chuck 22 increases.

For example, an appropriate value of the radio frequency power HF for plasma generation differs depending on a process to be performed. For example, in FIG. 2A, the radio frequency power HF for plasma generation is assumed to be set at 1000 W. Next, in FIG. 2B, when the radio frequency power HF for plasma generation is set at 2000 W, the electron density Ne in the plasma at the time of FIG. 2B is higher than the electron density Ne in the plasma at the time of FIG. 2A.

In contrast, as discussed above, the value of the direct-current voltage HV applied to the electrostatic chuck 22 is constant. Due to this, the attracting force of the electrostatic chuck 22 at the time of FIG. 2B is higher than the attracting force at the time of FIG. 2A by a value corresponding to “1000 W” that is the difference between the radio frequency power supplied at the time of FIG. 2A and FIG. 23. Thus, the attracting force of the electrostatic chuck 22 at the time of FIG. 23 is higher than the attracting force at the time of FIG. 2A. As a result, the distance between the focus ring 24 and the electrostatic chuck 22 at the time of FIG. 23 is narrower than the distance at the time of FIG. 2A.

In FIG. 2C, the radio frequency power HF for plasma generation is set at 1000 W again. Thus, the attracting force of the electrostatic chuck 22 becomes lower than the attracting force at the time of FIG. 2B. As a result, the distance between the focus ring 24 and the electrostatic chuck 22 at the time of FIG. 2C is wider than the distance at the time of FIG. 2B. On this occasion, the charge transfer from the focus ring 24 to the electrostatic chuck 22 occurs. Thus, the attracting force between the focus ring 24 and the electrostatic chuck 22 weakens, and the leakage quantity of the heat transfer gas supplied to the gap between the electrostatic chuck 22 and the focus ring 24 increases.

To reduce the leakage quantity of the heat transfer gas, the negative charge transfer from the back surface of the focus ring 24 to the top surface of the electrostatic chuck 22 needs to be prevented or reduced. To achieve this, in the present embodiment, the back surface of the focus ring 24 contacting the electrostatic chuck 22 is roughened. More specifically, the surface roughness Ra of the back surface of the focus ring 24 according to the present embodiment is made greater than or equal to 0.1 micrometers.

FIGS. 3A through 3C illustrate examples of states of electric charge between the focus ring 24 and the electrostatic chuck 22 when using the focus ring 24 having the back surface with the surface roughness Ra of 0.1 micrometers or more according to the present embodiment. The back surface of the focus ring 24 according to the present embodiment is processed by using a file and the like to have the surface roughness Ra of 0.1 micrometers or more. However, the method of processing the back surface of the focus ring 24 according to the present embodiment is not limited to this, and for example, the surface roughness Ra of the back surface is made 0.1 micrometers or more by blasting.

When using the focus ring 24 according to the present embodiment, the contact area between the focus ring 24 and the electrostatic chuck 22 is smaller than the contact area when using the focus ring 24 having the mirror-like back surface due to the concavities and convexities of the back surface of the focus ring 24. Thus, the contact resistance generated at the back surface of the focus ring 24 can be increased. Increasing the contact resistance makes difficult the electric charge transfer from the focus ring 24 to the electrostatic chuck 22. As a result, the negative electric charge in the back surface of the focus ring 24 is prevented from being transferred to the electrostatic chuck 22, and the decrease in attracting force between the focus ring 24 and the electrostatic chuck 22 can be prevented. Thus, the increase in leakage quantity of the heat transfer gas supplied to the gap between the focus ring 24 and the electrostatic chuck 22 can be prevented.

According to the focus ring 24 of the present embodiment, the attracting force between the focus ring 24 and the electrostatic chuck 22 can be maintained even in the process of repeating the supply of the low-power radio frequency power and the high-power radio frequency power from the second radio frequency power source 31. Hence, according to the present embodiment, the increase in leakage quantity of the heat transfer gas supplied to the gap between the focus ring 24 and the electrostatic chuck 22 can be prevented in a variety of processes.

[Experimental Results of Leakage Quantity]

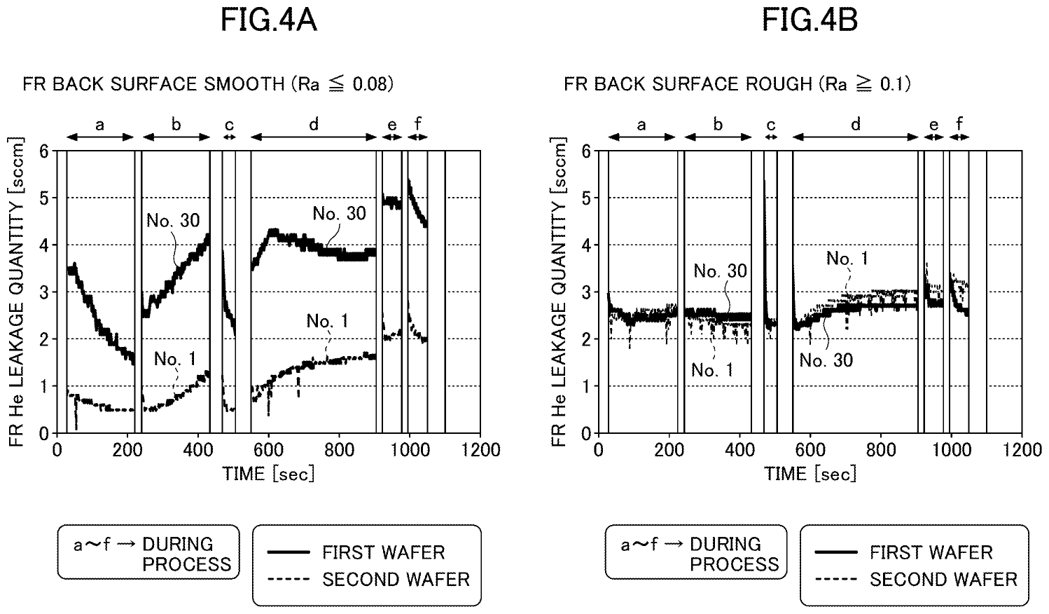

Next, the relationship between the surface roughness Ra of the back surface of the focus ring 24 according to the present embodiment and the leakage quantity of the heat transfer gas is described below with reference to FIGS. 4A and 4B. In the present embodiment, helium (He) gas is supplied to the gap between the back surfaces of the wafer W and the focus ring 24 and the top surface of the electrostatic chuck 22 as the heat transfer gas.

The vertical axis of FIG. 4A shows the amount of helium gas leaking out of the gap between the focus ring 24 and the electrostatic chuck 22 when the back surface of the focus ring 24 is smooth (when the surface roughness Ra≤0.08 micrometers).

The vertical axis of FIG. 4B shows the amount of helium gas leaking out of the gap between the focus ring 24 and the electrostatic chuck 22 when the back surface of the focus ring 24 is rough (when the surface roughness Re 0.1 micrometers).

The horizontal axes of FIGS. 4A and 4B show time. Each period of time a-f shows a period of time during a process. More specifically, curves shown by No. 1 and No. 30 in each period of time a-f indicate a leakage quantity of helium gas in each process a-f when the first wafer (No. 1) and the thirtieth wafer (No. 30) are processed with plasma in the substrate processing apparatus 10.

According to the experimental results, as shown in FIG. 4A, when the back surface of the focus ring 24 was smooth while the leakage quantity of helium gas of the first wafer (No. 1) was about 1 sccm, the leakage quantity of helium gas of the thirtieth wafer (No. 30) rose to about 3 to 4 scorn. As shown in FIG. 4A, this result indicated that when the back surface of the focus ring 24 was smooth, the leakage quantity of helium gas increased as the number of the processed wafers increased.

In contrast, as shown in FIG. 4B, when the back surface of the focus ring 24 was rough, the leakage quantity of helium gas was 2.5 sccm±0.5 sccm in both of the first wafer (No. 1) and the thirtieth wafer (No. 30). As shown in FIG. 4B, this result indicated that when the back surface of the focus ring 24 was rough, the leakage quantity of helium gas hardly change even when the number of the processed wafers was many.

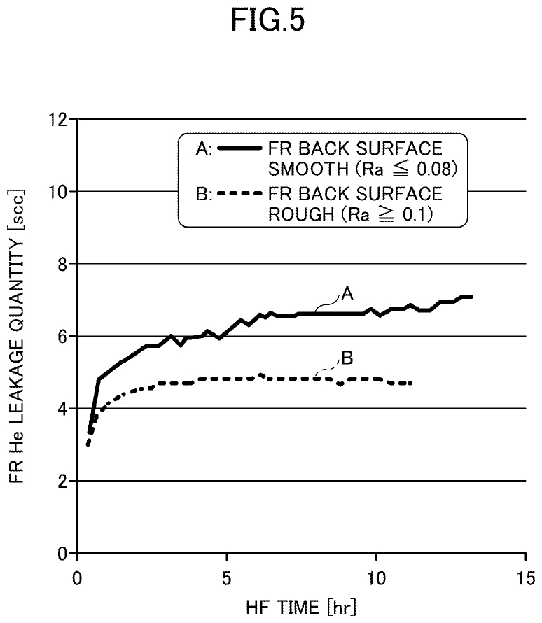

The relationship between the surface roughness Ra in the back surface of the focus ring 24 according to the present embodiment and the leakage quantity of the heat transfer gas is further described below with reference to FIG. 5. The horizontal axis in FIG. 5 shows accumulated time of the radio frequency power HF supplied during the process. The vertical axis in FIG. 5 shows the leakage quantity of helium gas leaking out of the gap between the focus ring 24 and the electrostatic chuck 22. The curve A shows the leakage quantity of helium gas when the back surface of the focus ring 24 is smooth (e.g., when the surface roughness Ra≤0.08 micrometers). The curve B shows the leakage quantity of helium gas when the back surface of the focus ring 24 is rough (i.e., when the surface roughness Ra≥0.1 micrometers).

The present result indicated that when the back surface of the focus ring 24 was smooth, the leakage quantity of helium gas increased as the number of the processed wafers increased. This showed that the charge transfer occurred (increased) over time between the electrostatic chuck 22 for electrostatically attracting the focus ring 24 thereto and the focus ring 24, and that the force for attracting the focus ring 24 thereto gradually decreased.

In contrast, the result indicated that when the back surface of the focus ring 24 was rough, the leakage quantity of helium gas did not change even when the number of the processed wafers increased. This showed that the charge transfer between the electrostatic chuck 22 and the focus ring 24 could be prevented and that the attraction characteristics of the focus ring 24 was stable.

The results indicated that the attraction characteristics of the focus ring 24 could be stabilized by performing the plasma process while using the focus ring 24 having the back surface of the surface roughness Ra≥0.1 micrometers in the substrate processing apparatus 10 according to the present embodiment. Thus, sealing characteristics between the focus ring 24 and the electrostatic chuck 22 could be stabilized, and the change in leakage quantity of the heat transfer gas could be prevented even when the number of the processed wafers increased.

[Experimental Results of Etching Rate]

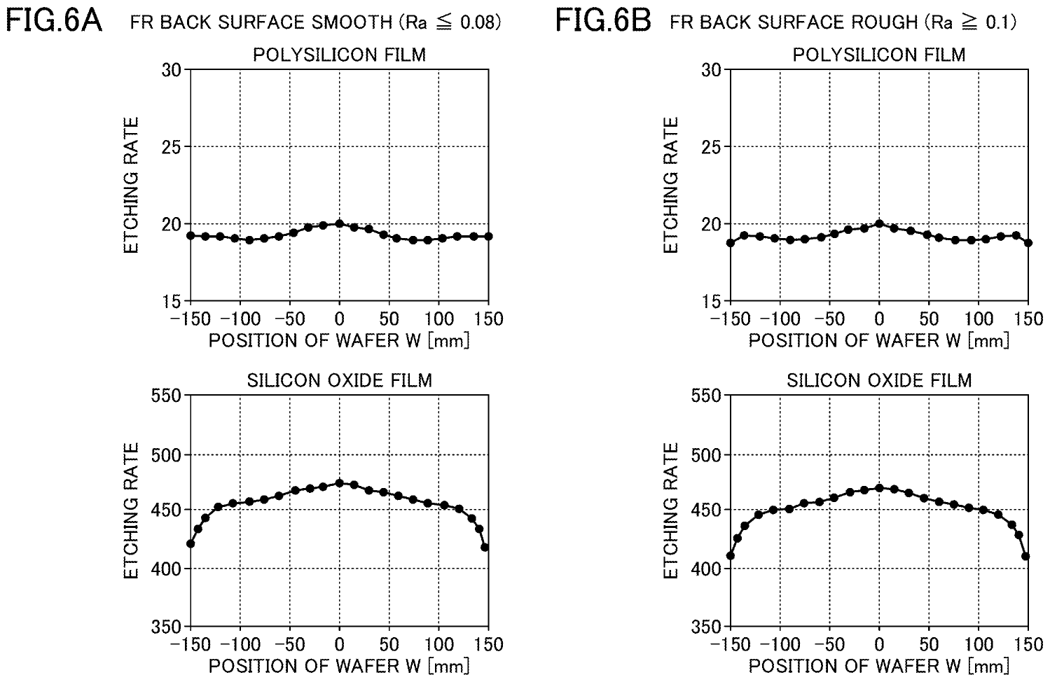

Finally, a result of the plasma etching process when using the focus ring 24 according to the present embodiment is described below with reference to FIGS. 6A and 6B.

The vertical axes of FIG. 6A show an etching rate when the back surface of the focus ring 24 was smooth (i.e., when the surface roughness Ra≤0.08 micrometers). The vertical axes of FIG. 6B show an etching rate when the back surface of the focus ring 24 was rough (i.e., when the surface roughness Ra≥0.1 micrometer).

The horizontal axes of FIGS. 6A and 6B show a position of the wafer W. In FIGS. 6A and 6B, etching rates in a diametrical direction of the wafer W with a diameter of 300 mm were measured. In FIGS. 6A and 6B, any one diametrical direction is made an x direction, and average values of the etching rates in the x direction and the y direction perpendicular to the x direction were plotted. The etching object films were two kinds of a polysilicon film and a silicon oxide film.

According to the experimental results, the etching rates when etching the polysilicon film and the silicon oxide film were approximately the same as each other in both cases where the back surface of the focus ring 24 was smooth as shown in FIG. 6A and where the back surface of the focus ring 24 was rough as shown in FIG. EB. Thus, it is noted that the attraction characteristics of the focus ring 24 can be stabilized and the change in leakage quantity of the heat transfer gas can be prevented while keeping the plasma processing characteristics preferable when using the focus ring 24 according to the present embodiment.

As discussed above, the focus ring 24 and the substrate processing apparatus 10 including the focus ring 24 according to the present embodiment have been described. According to the focus ring 24 of the present embodiment, the back surface of the focus ring 24 (i.e., the contact surface of the focus ring 24 with the electrostatic chuck 22) has the surface roughness Ra of 0.1 micrometers or more. Thus, the contact resistance generated at the back surface of the focus ring 24 can be increased; the attraction characteristics of the focus ring 24 can be stabilized; the leakage quantity of the heat transfer gas can be reduced; and the sealing characteristics of the gas can be increased.

However, when the back surface of the focus ting 24 is made too rough, it is concerned that the attraction characteristics of the focus ring 24 deteriorate and that the leakage quantity of the heat transfer gas increases. In other words, when the back surface of the focus ring 24 is made too rough, the distance between the focus ring 24 and the electrostatic chuck 22 physically increases.

More specifically, because the distance between the focus ring 24 and the electrostatic chuck 22 increases as the surface roughness Ra of the back surface of the focus ring 24 increases, Coulomb's force and the like between the positive charge in the top surface of the electrostatic chuck 22 and the negative charge in the back surface of the focus ring 24 decrease. As a result, the attracting force of the focus ring 24 weakens, and the leakage quantity of the heat transfer gas increases. Therefore, the surface roughness Ra of the back surface of the focus ring 24 is preferably 1.0 micrometers or less. In other words, the surface roughness Ra of the back surface of the focus ring 24 according to the present embodiment is preferably greater than or equal to 0.1 micrometers and smaller than or equal to 1.0 micrometers.

Thus, according to the embodiments, an increase in leakage quantity of a heat transfer gas can be prevented by stabilizing attraction characteristics of a focus ring.

Although the focus ring and the substrate processing apparatus have been described above according to the embodiments, the focus ring and the substrate processing apparatus of the present invention are not limited to the above-discussed embodiments. Various modifications and improvements can be made without departing from the scope of the invention. Moreover, the embodiments and modifications can be combined as long as they are not contradictory to each other.

For example, in the above embodiments, the back surface of the focus ring 24 has been set at the surface roughness Ra of 0.1 micrometers or more and 1.0 micrometers or less. However, at least one of the contact surfaces of the focus ring 24 and the electrostatic chuck 22 that contact with each other thereat just has to be processed so as to have the surface roughness Ra of 0.1 micrometers or more. Furthermore, at least one of the contact surfaces of the focus ring 24 and the electrostatic chuck 22 that contact with each other thereat is preferably processed so as to have the surface roughness Ra of 1.0 micrometers or less.

The focus ring of the present invention can be applied not only to the substrate processing apparatus of the capacitively coupled plasma as illustrated in FIG. 1 but also to other types of substrate processing apparatuses. The other types of substrate processing apparatuses include an inductively coupled plasma (ICP) apparatus, a substrate processing apparatus using a radial line slot antenna, a helicon wave excited plasma (HWP) apparatus, an electron cyclotron resonance plasma (ECR) apparatus and the like.

Although the wafer W has been described as an etching object in the present specification, a variety of substrates used for an LCD (Liquid Crystal Display), an FPD (Flat Panel Display) and the like, a photomask, a CD substrate, a printed circuit board and the like may be used as the etching object.

What is claimed is:

1. A substrate processing apparatus comprising:
a lower electrode including an electrostatic attraction mechanism configured to electrostatically attract a substrate thereon;
a focus ring disposed on a peripheral portion of the lower electrode in a process container so as to contact the electrostatic attraction mechanism of the lower electrode; and
a radio frequency power source configured to supply radio frequency power into the process container,
wherein a contact surface of the focus ring is made of any one of a silicon-containing material, alumina and silicon carbide,
wherein at least one of the contact surface of the focus ring and a contact surface of the electrostatic attraction mechanism of the lower electrode has surface roughness of 0.1 micrometers or more.

2. The substrate processing apparatus as claimed in claim 1, wherein the electrostatic chuck mechanism includes a first electrostatic attraction mechanism for the substrate and a second electrostatic attraction mechanism for the focus ring.
